(19) United States
(12) Patent Application Publication
(10) Pub. No.: US 2007/0272931 A1
(43) Pub. Date: Nov. 29, 2007

(54) Methods, devices and systems producing illumination and effects

(75) Inventor: Jonathan Gorrell, Gainesville, FL (US)

Correspondence Address: DAVIDSON BERQUIST JACKSON & GOWDEY LLP, 4300 WILSON BLVD., 7TH FLOOR, ARLINGTON, VA, 22203, US

(73) Assignee: Virgin Islands Microsystems, Inc., St. Thomas, VI (US)

(21) Appl. No.: 11/418,089

(22) Filed: May 5, 2006

(51) Int. Cl. H01L 33/00

(52) U.S. Cl. 257/79

(57) ABSTRACT

A device has a plurality of ultra-small resonant structures, each of said structures constructed and adapted to emit light at a particular wavelength when a beam of charged particles is passed nearby, wherein at least one of the light emitters emits light in a first range of wavelengths and wherein at least another of said light emitters emits light in a second range of wavelengths, distinct from said first range of wavelengths; and a controller mechanism constructed and adapted to selectively switch different ones of said light emitters on and off, whereby said device emits light in said first range of wavelengths or said second range of wavelengths. The wavelengths may be selected to emulate or provide warm light, cold light.

### CROSS-REFERENCE TO RELATED APPLICATIONS

The present invention is related to the following co-pending U.S. Patent applications which are all commonly owned with the present application, the entire contents of each of which are incorporated herein by reference:
(1) U.S. patent application Ser. No. 11/238,991, filed Sep. 30, 2005, entitled “Ultra-Small Resonating Charged Particle Beam Modulator”;
(2) U.S. patent application Ser. No. 10/917,511, filed on Aug. 13, 2004, entitled “Patterning Thin Metal Film by Dry Reactive Ion Etching”;
(3) U.S. application Ser. No. 11/203,407, filed on Aug. 15, 2005, entitled “Method Of Patterning Ultra-Small Structures”;
(4) U.S. application Ser. No. 11/243,476, filed on Oct. 5, 2005, entitled “Structures And Methods For Coupling Energy From An Electromagnetic Wave”;
(5) U.S. application Ser. No. 11/243,477, filed on Oct. 5, 2005, entitled “Electron beam induced resonance,”
(6) U.S. application Ser. No. 11/325,448, entitled “Selectable Frequency Light Emitter from Single Metal Layer,” filed Jan. 5, 2006;
(7) U.S. application Ser. No. 11/325,432, entitled, “Matrix Array Display,” filed Jan. 5, 2006,
(8) U.S. application Ser. No. 11/410,924, entitled, “Selectable Frequency EMR Emitter,” filed Apr. 26, 2006 [Atty. Docket 2549-0010].

### COPYRIGHT NOTICE

A portion of the disclosure of this patent document contains material which is subject to copyright or mask work protection. The copyright or mask work owner has no objection to the facsimile reproduction by anyone of the patent document or the patent disclosure, as it appears in the Patent and Trademark Office patent file or records, but otherwise reserves all copyright or mask work rights whatsoever.

### FIELD OF THE DISCLOSURE

This relates to ultra-small resonant EMR structures, and, more particularly, to methods, devices and systems producing illumination and effects using such structures.

### INTRODUCTION

The related applications describe various ultra-small electromagnetic radiation (EMR) emitting structures. The wavelength/frequency of the emitted EMR may be controlled or may depend on the structure used.

It is desirable to provide solid-state lighting and special illumination effects using such ultra-small structures.

### BRIEF DESCRIPTION OF THE DRAWINGS

The following description, given with respect to the attached drawings, may be better understood with reference to the non-limiting examples of the drawings, wherein:

FIGS. 1-2 show solid-state light-emitting devices; and

FIG. 3 is an example graph of amplitude versus frequency for the visible light spectrum.

### THE PRESENTLY PREFERRED EXEMPLARY EMBODIMENTS

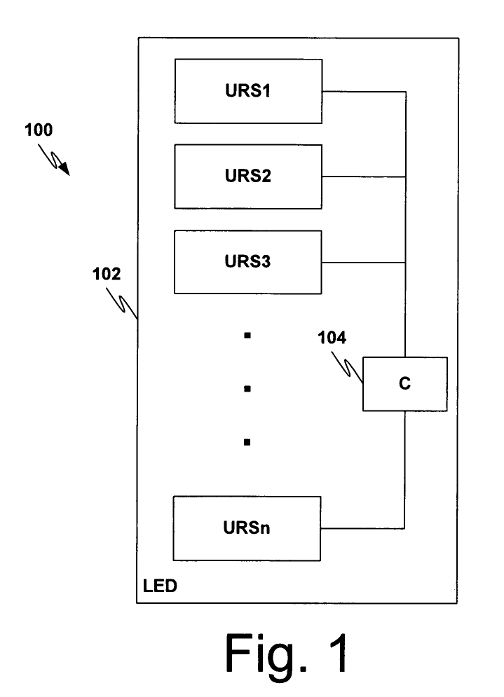

As shown in FIG. 1, a solid-state light-emitting device (light emitter) 100 consists of a number of ultra-small resonant structures (URS1 . . . URSn). These may be provided on a single substrate 102. Each of the ultra-small resonant structures (URSi) may be one of the EMR emitting structures described in the related applications which emit EMR when a beam of charged particles passes nearby. E.g., a URS may consist of a number of sub-structures arranged in a row. As described in the related applications, the charged particle beam can include ions (positive or negative), electrons, protons and the like. The beam may be produced by any source, including, e.g., without limitation an ion gun, a thermionic filament, a tungsten filament, a cathode, a field-emission cathode, a planar vacuum triode, an electron-impact ionizer, a laser ionizer, a chemical ionizer, a thermal ionizer, an ion-impact ionizer.

Each of the ultra-small resonant structures is constructed and adapted to emit light at a particular wavelength/frequency (or within a particular range of wavelengths). Thus, a particular device 100 may emit light at a number (n) of wavelengths. In some embodiments, URSi are constructed and adapted so that in conjunction, the emit light across a range of visible wavelengths. Those skilled in the art will realize and understand, upon reading this description, that the number of wavelengths depends on the number of ultra-small structures used.

In some embodiments, a controller 104 may be used to selectively control the various URSi so that some or all of them are on/off at different times.

The source of charged particles is not shown in the drawing. Those skilled in the art will realize and understand, upon reading this description, that the source of charged particles may be on the same substrate 102 as the ultra-small devices or that it may be elsewhere. Those skilled in the art will also realize and understand, upon reading this description, that more than one source of charged particles may be used with any particular device. For example, there may be a single source for the entire device 100, each individual ultra-small structure may have its own source, or groups of ultra-small structures may share sources of charged particles.

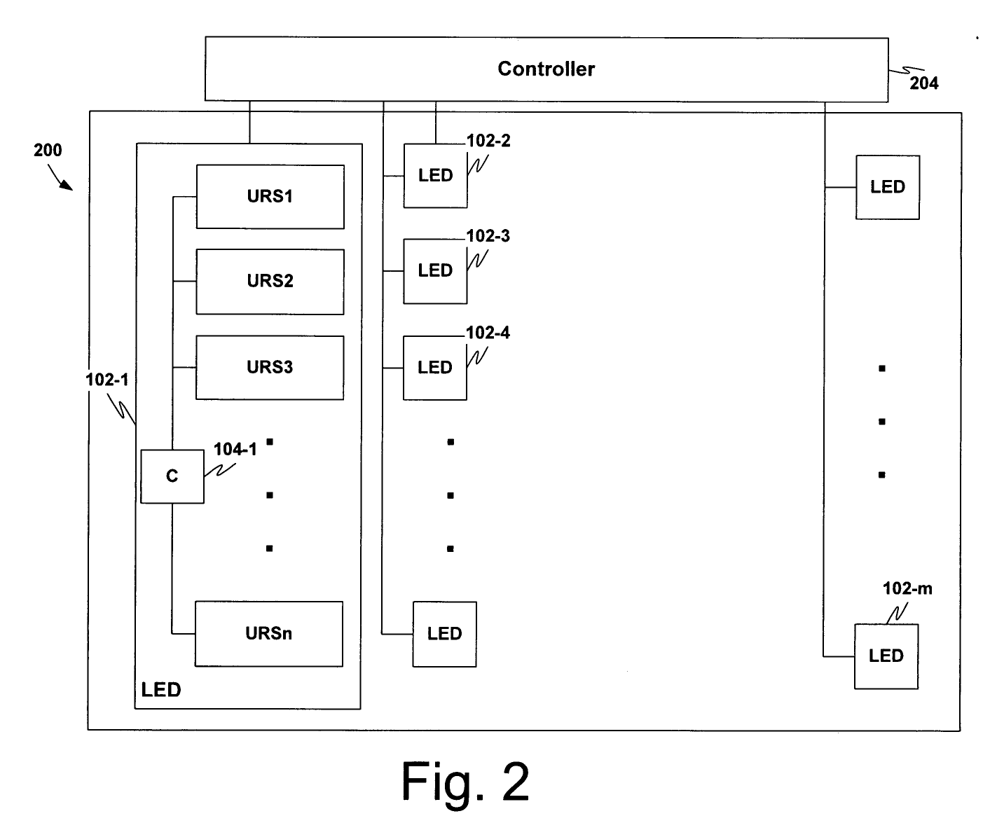

FIG. 2 shows a light-emitting structure 200 made up of a collection of light emitters 102-j (as described above) formed, e.g., on a substrate. Each of the light emitters 102-j may be identical, or different ones of the light emitters 102-j may be constructed and adapted to emit light at a different wavelength (or group of wavelengths). The various light emitters may be arranged in any way on the substrate. For example, the light emitters may be arranged in a rectangular form on the substrate. Combinations of light-emitting structures 200 may be combined to provide different light intensities.

In some embodiments, the various ultra-small structures may be constructed and adapted to emit light at application-specific wavelengths. For example, a light-emitting structure may be made up of light emitters that emit so-called “warm light”. In this manner, different lighting conditions can be created. For example, light-emitting structures 200 can emit “warm light”, “cold light”, simulated fluorescent light, full spectrum light, light of different colors, etc. In some embodiments, a controller or switching mechanism 204 may be operatively connected to some or all of the light emitters in order to control their respective on/off states as well as their respective emitted wavelengths.

A light-emitting structure may be (or may be incorporated in) any kind of light or light fixture, including room lighting fixtures, workspace lighting (e.g., desk lighting), vehicle lighting and the like.

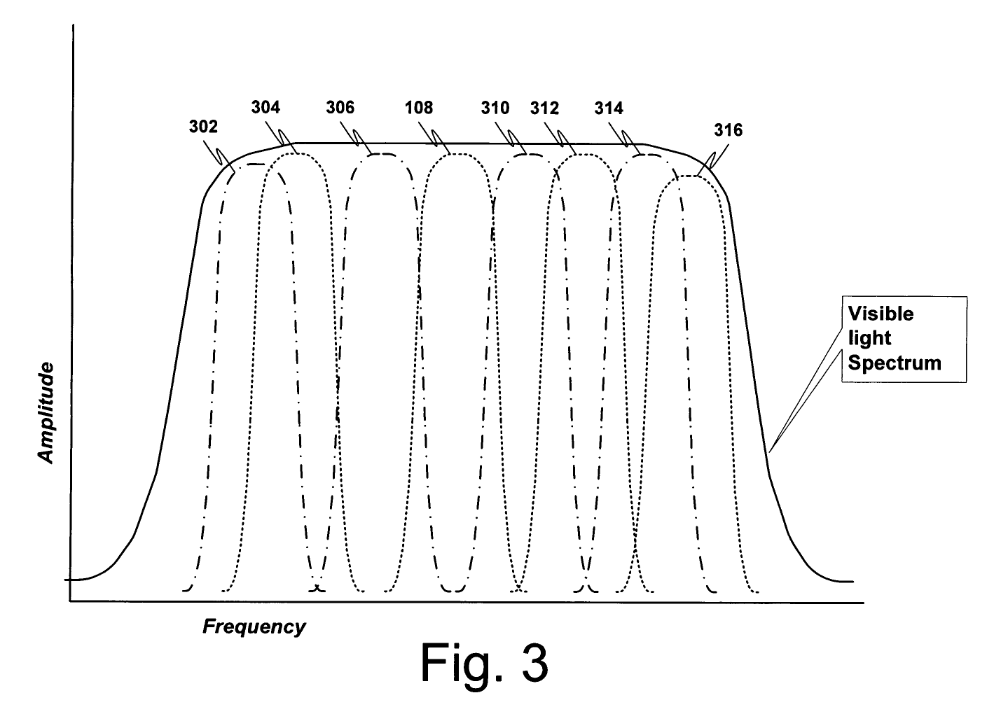

FIG. 3 illustrates an example spectrum, e.g., corresponding to visible light. The controllers 104, 204 (in FIG. 1 or 2) can be used to select USRi and their intensity levels so a user can select color and intensity levels for their particular environment or application. The various regions (denoted 302, 304, 306, . . . , 316) are regions of various one or more URSi that can be chosen individually or collectively (for a full visible light spectrum).

The devices described herein may be made, e.g., using techniques such as described in U.S. patent application Ser. No. 10/917,511, entitled “Patterning Thin Metal Film by Dry Reactive Ion Etching” and/or U.S. application Ser. No. 11/203,407, entitled “Method Of Patterning Ultra-Small Structures,” both of which have been incorporated herein by reference. The nano-resonant structure may comprise any number of resonant microstructures constructed and adapted to produce EMR, e.g., as described above and/or in U.S. application Ser. No. 11/325,448, entitled “Selectable Frequency Light Emitter from Single Metal Layer,” filed Jan. 5, 2006 [Atty. Docket 2549-0060], U.S. application Ser. No. 11/325,432, entitled, “Matrix Array Display,” filed Jan. 5, 2006, and U.S. application Ser. No. 11/243,476 [Atty. Docket 2549-0058], filed on Oct. 5, 2005, entitled “Structures And Methods For Coupling Energy From An Electromagnetic Wave”; U.S. application Ser. No. 11/243,477 [Atty. Docket 2549-0059], filed on Oct. 5, 2005, entitled “Electron beam induced resonance;” and U.S. application Ser. No. 11/302,471, entitled “Coupled Nano-Resonating Energy Emitting Structures,” filed Dec. 14, 2005 [atty. docket 2549-0056].

While certain configurations of structures have been illustrated for the purposes of presenting the basic structures of the present invention, one of ordinary skill in the art will appreciate that other variations are possible which would still fall within the scope of the appended claims. While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

We claim:

1. A light-emitting device comprising:
a plurality of ultra-small resonant structures, each of said structures constructed and adapted to emit light at a particular wavelength when a beam of charged particles is passed nearby, wherein at least two of said ultra-small resonant structures emitting light at different wavelengths.

2. A device as in claim 1 wherein at least four of the ultra-small resonant structures emit light at different wavelengths.

3. A device as in claim 1 further comprising:
a controller constructed and adapted to selectively switch on and off at least some of the plurality of ultra-small resonant structures.

4. A device as in claim 1 wherein there are at least N ultra-small resonant structures, for N at least 2, and wherein there are between 2 and N distinct wavelengths emitted by said device.

5. A device as in claim 4 wherein N is a value selected from the group 3-100.

6. A device comprising:
a plurality of light-emitters, each said light emitter comprising:
a plurality of ultra-small resonant structures, each of said structures constructed and adapted to emit light at a particular wavelength when a beam of charged particles is passed nearby, wherein
at least one of the light emitters emits light in a first range of wavelengths and wherein at least another of said light emitters emits light in a second range of wavelengths, distinct from said first range of wavelengths; and
a controller mechanism constructed and adapted to selectively switch different ones of said light emitters on and off, whereby said device emits light in said first range of wavelengths or said second range of wavelengths.

7. A method comprising:
providing a plurality of light emitters, each light emitter comprising: a plurality of ultra-small resonant structures, each of said structures constructed and adapted to emit light at a particular wavelength when a beam of charged particles is passed nearby, wherein at least one of the light emitters emits light in a first range of wavelengths and wherein at least another of said light emitters emits light in a second range of wavelengths, distinct from said first range of wavelengths; and
causing at least some of the plurality of light emitters to be activated.

8. A method as in claim 1 wherein said at least two light emitters are activated at the same time, whereby light is emitted at the first range of wavelengths and at the second range of wavelengths at the same time.

9. A method as in claim 1 wherein said at least two light emitters are activated at different times, whereby light is emitted a the first range of wavelengths and at the second range of wavelengths at different times.

10. A method as in claim 1 wherein at least some of the plurality of light emitters emit light at wavelengths corresponding, in combination, to warm light.

11. A method as in claim 1 wherein at least some of the plurality of light emitters emit light at wavelengths corresponding, in combination, to cold light.

12. A method as in claim 1 wherein at least some of the plurality of light emitters emit light at wavelengths corresponding, in combination, to full-spectrum light.
